(19) United States
(12) Patent Application Publication
(10) Pub. No.: US 2023/0260997 A1
(43) Pub. Date: Aug. 17, 2023

(54) SEMICONDUCTOR DEVICE

(71) Applicant: Kioxia Corporation, Tokyo (JP)

(72) Inventors: Kota KATO, Yokkaichi (JP); Shingo NAKAJIMA, Yokkaichi (JP); Kaori KAWASAKI, Yokohama (JP); Shoichi WATANABE, Kawasaki (JP)

(73) Assignee: Kioxia Corporation, Tokyo (JP)

(21) Appl. No.: 17/864,555

(22) Filed: Jul. 14, 2022

(30) Foreign Application Priority Data
Feb. 15, 2022 (JP) 2022-021486

(51) Int. Cl. H01L 27/092; H01L 23/535; H01L 21/768; H01L 21/8238

(52) U.S. Cl. CPC H01L 27/092; H01L 23/535; H01L 21/76805; H01L 21/76831; H01L 21/76895; H01L 21/823871

(57) ABSTRACT

A semiconductor device according to an embodiment includes: first and second gate electrodes; first and second spacer layers respectively covering the first and second gate electrodes; first and second liner layers respectively covering the first and second gate electrodes with the first and second spacer layers interposed therebetween; a first contact extending from above the first liner layer to below the first spacer layer and including a first conductive layer connected to the first gate electrode; and a second contact extending from above the second liner layer to below the second spacer layer and including a second conductive layer connected to the second gate electrode. The first conductive layer is in contact with the first spacer layer on the side surface via a first insulating layer covering a sidewall of the first conductive layer. The second conductive layer is in direct contact with the second spacer layer on the side surface.

### CROSS-REFERENCE TO RELATED APPLICATIONS

This application is based upon and claims the benefit of priority from Japanese Patent Application No. 2022-021486, filed on Feb. 15, 2022; the entire contents of which are incorporated herein by reference.

### FIELD

Embodiments described herein relate generally to a semiconductor device.

### BACKGROUND

In a semiconductor device including a CMOS transistor or the like, it is desired to improve various characteristics of transistors such as a leakage current between transistors, a resistance value of a poly/metal interface in a poly/metal gate structure, and negative bias temperature instability.

### BRIEF DESCRIPTION OF THE DRAWINGS

FIG. 1 is a cross-sectional view illustrating an example of a configuration of a semiconductor device according to an embodiment;

FIGS. 2A to 2C are cross-sectional views sequentially illustrating a part of the procedure of the method for manufacturing the semiconductor device according to the embodiment;

FIGS. 3A and 3B are cross-sectional views sequentially illustrating a part of the procedure of the method for manufacturing the semiconductor device according to the embodiment;

FIGS. 4A and 4B are cross-sectional views sequentially illustrating a part of the procedure of the method for manufacturing the semiconductor device according to the embodiment;

FIGS. 5A and 5B are cross-sectional views sequentially illustrating a part of the procedure of the method for manufacturing the semiconductor device according to the embodiment;

FIGS. 6A and 6B are cross-sectional views sequentially illustrating a part of the procedure of the method for manufacturing the semiconductor device according to a comparative example;

FIGS. 7A and 7B are cross-sectional views sequentially illustrating a part of the procedure of the method for manufacturing the semiconductor device according to a comparative example;

FIGS. 8A to 8C are partially enlarged cross-sectional views of the semiconductor device according to the embodiment and the comparative example;

FIGS. 9A and 9B are cross-sectional views sequentially illustrating a part of the procedure of the method for manufacturing the semiconductor device according to a first modification of the embodiment;

FIGS. 10A and 10B are cross-sectional views sequentially illustrating a part of the procedure of the method for manufacturing the semiconductor device according to the first modification of the embodiment;

FIGS. 11A and 11B are diagrams sequentially illustrating a part of the procedure of the method for manufacturing the semiconductor device according to a second modification of the embodiment;

FIGS. 12A and 12B are diagrams sequentially illustrating a part of the procedure of the method for manufacturing the semiconductor device according to the second modification of the embodiment;

FIGS. 13A and 13B are diagrams sequentially illustrating a part of the procedure of the method for manufacturing the semiconductor device according to the second modification of the embodiment;

FIGS. 14A and 14B are diagrams sequentially illustrating a part of the procedure of the method for manufacturing the semiconductor device according to the second modification of the embodiment;

FIG. 15 is a block diagram of a semiconductor memory device according to another embodiment; and

FIG. 16 is an equivalent circuit diagram illustrating an example of a configuration of a memory cell array and a row decoder included in a semiconductor memory device according to another embodiment.

### DETAILED DESCRIPTION

A semiconductor device according to an embodiment includes: first and second gate electrodes; first and second spacer layers respectively covering the first and second gate electrodes; first and second liner layers respectively covering the first and second gate electrodes with the first and second spacer layers interposed therebetween; a first contact extending from above the first liner layer to below the first spacer layer and including a first conductive layer connected to the first gate electrode; and a second contact extending from above the second liner layer to below the second spacer layer and including a second conductive layer connected to the second gate electrode, wherein the first conductive layer is in contact with the first spacer layer on a side surface via a first insulating layer covering a sidewall of the first conductive layer, and the second conductive layer is in direct contact with the second spacer layer on a side surface.

Hereinafter, the present invention will be described in detail with reference to the drawings. Note that the present invention is not limited by the following embodiments. In addition, constituent elements in the following embodiments include those that can be easily assumed by those skilled in the art or those that are substantially the same.

### Embodiment

Hereinafter, embodiments will be described in detail with reference to the drawings.

(Configuration of Semiconductor Device)

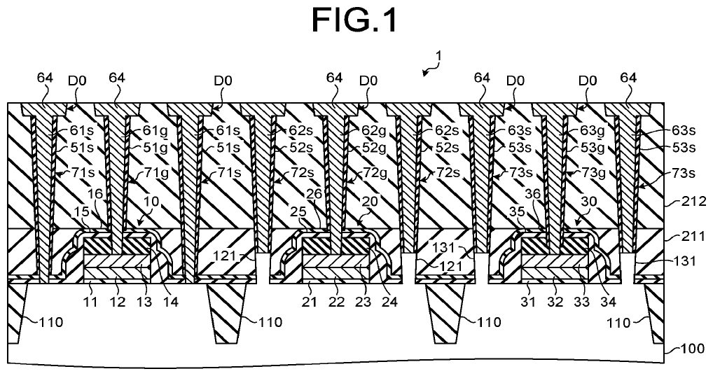

FIG. 1 is a cross-sectional view illustrating an example of a configuration of a semiconductor device 1 according to an embodiment. In the present specification, a surface of a substrate 100 on which a transistor 10 and the like described later are formed is defined as an upper surface, and a direction in which a polysilicon electrode 12, a metal electrode 13, and the like of the transistor 10 are stacked is defined as an upper side of the semiconductor device 1.

As illustrated in FIG. 1, the semiconductor device 1 includes transistors 10 to 30, interlayer insulating layers 211 and 212, contacts 71s to 73s and 71g to 73g, and wiring DO provided on the substrate 100.

The substrate 100 is, for example, a semiconductor substrate such as a silicon substrate. The substrate 100 is provided with an element isolation layer 110 that electrically isolates formation regions of the transistors 10 to 30 from each other. That is, the transistors 10 to 30 are electrically isolated from each other. In the formation regions of the transistors 10 to 30 in the substrate 100, a dopant of a predetermined conductivity type is diffused to form a source/drain region.

A plurality of transistors 10 to 30 is provided on the substrate 100. However, these transistors 10 to 30 may not be arranged on the substrate 100 in the arrangement order of FIG. 1. In addition, these transistors 10 to 30 may not be adjacent to each other with the element isolation layer 110 interposed therebetween. In addition, the number and type of the transistors 10 to 30 provided on the substrate 100 may vary.

The transistor 10 is configured as, for example, a high voltage (HV) N-channel metal oxide semiconductor (MOS) transistor.

The transistor 10 includes a gate insulating layer 11, a polysilicon electrode 12, a metal electrode 13, and a cap layer 14 as a second cap layer, which are stacked in this order from the substrate 100 side. The polysilicon electrode 12 and the metal electrode 13 constitute a gate electrode of the transistor 10 as a second gate electrode. In other words, the transistor 10 is configured as a transistor having a poly/metal gate structure.

In addition, the transistor 10 includes a spacer layer 15 as a second spacer layer that covers the side surfaces of the gate insulating layer 11, the polysilicon electrode 12, the metal electrode 13, and the cap layer 14 and the upper surface of the cap layer 14, and a liner layer 16 as a second liner layer that covers the spacer layer 15.

The transistor 20 is configured as, for example, a low voltage/very low voltage (LV/VLV) P-channel MOS transistor.

The transistor 20 includes a gate insulating layer 21, a polysilicon electrode 22, a metal electrode 23, and a cap layer 24 as a second cap layer, which are stacked in this order from the substrate 100 side. The polysilicon electrode 22 and the metal electrode 23 constitute a gate electrode of the transistor 20 as a second gate electrode. In other words, the transistor 20 is configured as a transistor having a poly/metal gate structure.

In addition, the transistor 20 includes a spacer layer 25 as a second spacer layer that covers the side surfaces of the gate insulating layer 21, the polysilicon electrode 22, the metal electrode 23, and the cap layer 24 and the upper surface of the cap layer 24, and a liner layer 26 as a second liner layer that covers the spacer layer 25.

The transistor 30 is configured as, for example, a high-voltage P-channel MOS transistor. Note that these transistors 10 and 30 are also referred to as high-breakdown-voltage MOS transistors.

The transistor 30 includes a gate insulating layer 31, a polysilicon electrode 32, a metal electrode 33, and a cap layer 34 as a first cap layer, which are stacked in this order from the substrate 100 side. The polysilicon electrode 32 and the metal electrode 33 constitute a gate electrode of the transistor 30 as a first gate electrode. In other words, the transistor 30 is configured as a transistor having a poly/metal gate structure.

In addition, the transistor 30 includes a spacer layer 35 as a first spacer layer that covers the side surfaces of the gate insulating layer 31, the polysilicon electrode 32, the metal electrode 33, and the cap layer 34 and the upper surface of the cap layer 34, and a liner layer 36 as a first liner layer that covers the spacer layer 35.

Here, the gate insulating layers 11 to 31 of these transistors 10 to 30 are, for example, a silicon oxide layer, a hafnium oxide layer, a zirconium oxide layer, or the like.

In addition, the polysilicon electrodes 12 to 32 are, for example, a conductive polysilicon layer or the like, and function as a poly gate as described above. The metal electrodes 13 to 33 are, for example, a tungsten silicide layer or the like, and function as a metal gate as described above.

The cap layers 14 to 34, the spacer layers 15 to 35, and the liner layers 16 to 36 are all insulating layers. The cap layers 14 to 34 and the liner layers 16 to 36 are, for example, a nitride layer such as a silicon nitride layer, and the spacer layers 15 to 35 are an oxide layer such as a silicon oxide layer. More specifically, the spacer layers 15 to 35 are, for example, a Tetra Ethoxy Silane (TEOS) layer or the like.

The spacer layers 15 to 35 and the liner layers 16 to 36 cover the polysilicon electrodes 12 to 32, the metal electrodes 13 to 33, and the like of the transistors 10 to 30, and also cover the substrate 100 therearound. The spacer layers 15 to 35 of the individual transistors 10 to 30 may cover the substrate 100 continuously with each other via the region between the transistors 10 to 30. Further, the liner layers 16 to 36 may continuously cover the spacer layers 15 to 35 via the region between the transistors 10 to 30.

The transistors 10 to 30 are entirely covered with interlayer insulating layers 211 and 212. The interlayer insulating layer 211 is, for example, a silicon oxide layer such as a non-doped silicate glass (NSG) layer and directly covers the transistors 10 to 30. The interlayer insulating layer 212 is, for example, a silicon oxide layer such as a TEOS layer, and covers the transistors 10 to 30 via the interlayer insulating layer 211.

The plurality of contacts 71s to 73s and 71g to 73g are connected to the transistors 10 to 30.

The contact 71g as the second contact penetrates the interlayer insulating layers 212 and 211, the liner layer 16, the spacer layer 15, and the cap layer 14 and is connected to the metal electrode 13 of the transistor 10. The contact 71g includes a conductive layer 61g as a second conductive layer and an insulating layer 51g as a second insulating layer.

The conductive layer 61g penetrates the interlayer insulating layers 212 and 211, the liner layer 16, the spacer layer 15, and the cap layer 14 and reaches the metal electrode 13 of the transistor 10. The conductive layer 61g is, for example, a metal layer such as a tungsten layer or a copper layer. The conductive layer 61g may be a metal layer or the like having a barrier metal layer (not illustrated) on the surface. The barrier metal layer may be, for example, a titanium layer, a titanium nitride layer, a tantalum layer, or a tantalum nitride layer.

The insulating layer 51g is a silicon oxide layer such as a low temperature oxide (LTO) layer, and covers the sidewall of the conductive layer 61g above the liner layer 16. That is, the insulating layer 51g extends in the interlayer insulating layers 212 and 211 and reaches the liner layer 16. More specifically, the lower end of the insulating layer 51g remains in the upper surface of the liner layer 16 or the liner layer 16 and does not penetrate the liner layer 16.

As a result, the conductive layer 61g of the contact 71g is in direct contact with the spacer layer 15 and the cap layer 14 on a side surface at the position below the liner layer 16. As described above, when the conductive layer 61g is a single metal layer or the like, the sidewall of the metal layer is in contact with the spacer layer 15 and the cap layer 14. When the conductive layer 61g is a metal layer or the like having a barrier metal layer, the barrier metal layer is in contact with the spacer layer 15 and the cap layer 14.

The pair of contacts 71s penetrates the interlayer insulating layers 212 and 211, the liner layer 16, and the spacer layer 15, and is connected to the source/drain regions provided on the substrate 100 on both sides of the polysilicon electrode 12 and the metal electrode 13 of the transistor 10. Each of the contacts 71s includes a conductive layer 61s and an insulating layer 51s.

The conductive layer 61s penetrates the interlayer insulating layers 212 and 211, the liner layer 16, and the spacer layer 15 and reaches the substrate 100 on both sides of the transistor 10. Similarly to the conductive layer 61g, the conductive layer 61s is a single metal layer, a metal layer having a barrier metal layer on the surface, or the like.

The insulating layer 51s is a silicon oxide layer such as an LTO layer, for example, similarly to the insulating layer 51g described above, and covers the sidewall of the conductive layer 61s above the liner layer 16. That is, the insulating layer 51s extends in the interlayer insulating layers 212 and 211 and reaches the liner layer 16. The conductive layer 61s of the contact 71s extends in the spacer layer 15 while being in direct contact with the spacer layer 15 on a side surface at a position below the liner layer 16, and is connected to the upper surface of the substrate 100.

The contact 72g as the second contact penetrates the interlayer insulating layers 212 and 211, the liner layer 26, the spacer layer 25, and the cap layer 24 and is connected to the metal electrode 23 of the transistor 20. The contact 72g includes a conductive layer 62g as a second conductive layer and an insulating layer 52g as a second insulating layer.

The conductive layer 62g penetrates the interlayer insulating layers 212 and 211, the liner layer 26, the spacer layer 25, and the cap layer 24 and reaches the metal electrode 23 of the transistor 20. The conductive layer 62g is a single metal layer, a metal layer having a barrier metal layer on the surface, or the like, similarly to the above-described conductive layer 61g and the like.

The insulating layer 52g is a silicon oxide layer such as an LTO layer, for example, similarly to the insulating layer 51g and the like described above, and covers the sidewall of the conductive layer 62g above the liner layer 26. That is, the insulating layer 52g extends in the interlayer insulating layers 212 and 211 and reaches the liner layer 26. More specifically, the lower end of the insulating layer 52g remains in the upper surface of the liner layer 26 or the liner layer 26 and does not penetrate the liner layer 26.

As a result, the conductive layer 62g of the contact 72g is in direct contact with the spacer layer 25 and the cap layer 24 on a side surface at the position below the liner layer 26. That is, the side surface of the metal layer which is the conductive layer 62g or the barrier metal layer included in the metal layer is in contact with the spacer layer 25 and the cap layer 24.

The pair of contacts 72s penetrates the interlayer insulating layers 212 and 211, the liner layer 26, and the spacer layer 25, and is connected to the source/drain regions provided in the substrate 100 on both sides of the polysilicon electrode 22 and the metal electrode 23 of the transistor 20 via the epitaxial layer 121. The epitaxial layer 121 is a layer obtained by epitaxially growing a crystalline silicon layer or the like from the upper surface of the substrate 100. Each of the contacts 72s includes a conductive layer 62s and an insulating layer 52s.

The conductive layer 62s penetrates the interlayer insulating layers 212 and 211, the liner layer 26, and the spacer layer 25 and reaches the substrate 100 on both sides of the transistor 20. Similarly to the above-described conductive layer 62g and the like, the conductive layer 61s is a single metal layer, a metal layer having a barrier metal layer on the surface, or the like.

The insulating layer 52s is a silicon oxide layer such as an LTO layer, for example, similarly to the insulating layer 51g and the like described above, and covers the sidewall of the conductive layer 62s above the liner layer 26. That is, the insulating layer 52s extends in the interlayer insulating layers 212 and 211 and reaches the liner layer 26. The conductive layer 62s of the contact 72s extends in the spacer layer 25 while being in direct contact with the spacer layer 25 on a side surface at a position below the liner layer 26, and is connected to the upper surface of the substrate 100.

The contact 73g as the first contact penetrates the interlayer insulating layers 212 and 211, the liner layer 36, the spacer layer 35, and the cap layer 34 and is connected to the metal electrode 33 of the transistor 30. The contact 73g includes a conductive layer 63g as a first conductive layer and an insulating layer 53g as a first insulating layer.

The conductive layer 63g penetrates the interlayer insulating layers 212 and 211, the liner layer 36, the spacer layer 35, and the cap layer 34 and reaches the metal electrode 33 of the transistor 30. The conductive layer 63g is a single metal layer, a metal layer having a barrier metal layer on the surface, or the like, similarly to the above-described conductive layer 61g and the like.

The insulating layer 53g is a silicon oxide layer such as an LTO layer, for example, similarly to the insulating layer 51g and the like described above, and covers the sidewall of the conductive layer 63g from the upper side to the lower side of the liner layer 36. That is, the insulating layer 53g penetrates the interlayer insulating layers 212 and 211, the liner layer 36, and the spacer layer 35, and reaches the cap layer 34. More specifically, the lower end of the insulating layer 53g reaches a predetermined depth of the cap layer 34.

As a result, the conductive layer 63g of the contact 73g is in contact with the spacer layer 53 on the side surface via the insulating layer 35g even at the position below the liner layer 36. In addition, the conductive layer 63g is in contact with the cap layer 34 at the side surface with the insulating layer 53g interposed therebetween up to a predetermined depth in the cap layer 34, and is in contact with the cap layer 53 at the side surface without the insulating layer 34g interposed therebetween below. That is, the side surface of the metal layer which is the conductive layer 63g or the barrier metal layer included in the metal layer is in contact with the spacer layer 35 and a part of the cap layer 34 in the depth direction.

The pair of contacts 73s penetrates the interlayer insulating layers 212 and 211, the liner layer 36, and the spacer layer 35, and is connected to the source/drain regions provided on the substrate 100 on both sides of the polysilicon electrode 32 and the metal electrode 33 of the transistor 30 via an epitaxial layer 131 such as a crystalline silicon layer. Each of the contacts 73s includes a conductive layer 63s and an insulating layer 53s.

The conductive layer 63s penetrates the interlayer insulating layers 212 and 211, the liner layer 36, and the spacer layer 35 and reaches the substrate 100 on both sides of the transistor 30. Similarly to the above-described conductive layer 63g and the like, the conductive layer 61s is a single metal layer, a metal layer having a barrier metal layer on the surface, or the like.

The insulating layer 53s is a silicon oxide layer such as an LTO layer, for example, similarly to the insulating layer 51g and the like described above, and covers the sidewall of the conductive layer 63s above the liner layer 36. That is, the insulating layer 53s extends in the interlayer insulating layers 212 and 211 and reaches the liner layer 36. The conductive layer 63s of the contact 73s extends in the spacer layer 35 while being in direct contact with the spacer layer 35 on the side surface at a position below the liner layer 36, and is connected to the upper surface of the substrate 100.

Each of the plurality of contacts 71s to 73s and 71g to 73g is connected to the wiring DO provided in the interlayer insulating layer 212 at the upper end. The wiring DO is, for example, a metal layer such as a tungsten layer or a copper layer. The wiring DO may be a metal layer or the like having a barrier metal layer (not illustrated) on the surface. In addition, the conductive layers 61s to 63s and 61g to 63g of the plurality of contacts 71s to 73s and 71g to 73g and the wiring DO may be the same kind of metal layer or different kinds of metal layers.

As a result, each of the individual transistors 10 to 30 is connected to a power supply, a semiconductor element, and the like (not illustrated) via the plurality of contacts 71s to 73s and 71g to 73g and the plurality of wirings DO.

For example, a relatively high gate voltage is applied to the polysilicon electrode 12 and the metal electrode 13 of the transistor 10 via the wiring DO and the contact 71g. Furthermore, for example, a gate voltage lower than that for the transistor 20 is applied to the polysilicon electrode 22 and the metal electrode 23 of the transistor 10 via the wiring DO and the contact 72g. In addition, a high gate voltage is applied to the polysilicon electrode 32 and the metal electrode 33 of the transistor 30 via the wiring DO and the contact 73g, for example, similarly to the transistor 10.

In addition, these transistors 10 to 30 are used as a drive circuit that drives, for example, a semiconductor element or the like electrically connected to these transistors 10 to 30 in various combinations.

In this case, among the transistors 10 to 30, for example, the transistors 10 can be a main configuration of the drive circuit, and the plurality of transistors 10 can be arranged in the drive circuit at high density. On the other hand, the transistors 20 and 30 can have an auxiliary configuration of the drive circuit, and a predetermined number of transistors 20 and 30 can be arranged in the drive circuit. At this time, for example, the transistor 20 configured as a low-voltage MOS transistor is applied to a portion in which high-speed operation is required in the drive circuit.

(Method of Manufacturing Semiconductor Device)

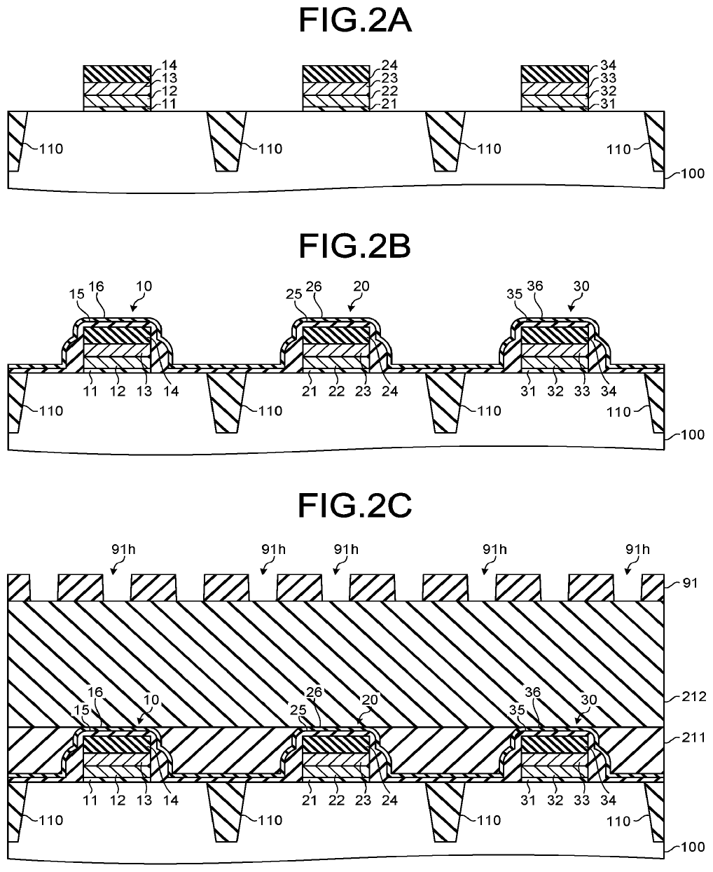

Next, a method for manufacturing the semiconductor device 1 according to the embodiment will be described with reference to FIGS. 2A to 5B. FIGS. 2A to 5B are cross-sectional views sequentially illustrating a part of the procedure of the method for manufacturing the semiconductor device 1 according to the embodiment.

As illustrated in FIG. 2A, a dopant of a predetermined conductivity type is diffused into the substrate 100 such as a silicon substrate.

In addition, an insulating layer such as a silicon oxide layer, and an insulating layer such as a polysilicon layer, a metal layer, and a silicon nitride layer are stacked in this order on the substrate 100, and formed into a predetermined shape by etching treatment or the like. As a result, the gate insulating layers 11 to 31, the polysilicon electrodes 12 to 32, the metal electrodes 13 to 33, and the cap layers 14 to 34 of each transistors 10 to 30 are formed.

Note that the element isolation layer 110 is formed on the substrate 100 after a polysilicon layer is formed, for example.

As illustrated in FIG. 2B, the spacer layers 15 to 35 are formed to cover the side surfaces of the gate insulating layers 11 to 31, the polysilicon electrodes 12 to 32, the metal electrodes 13 to 33, and the cap layers 14 to 34, and the upper surface of the cap layers 14 to 34. At this time, by forming a silicon oxide layer such as a TEOS layer over the entire upper surface of the substrate 100, these spacer layers 15 to 35 may be integrally formed.

In addition, the liner layers 16 to 36 covering the spacer layers 15 to 35 are formed. At this time, by forming an insulating layer such as a silicon nitride layer over the entire upper surface of the substrate 100, these liner layers 16 to 36 may be integrally formed.

Thus, the transistors 10 to 30 are formed.

As illustrated in FIG. 2C, an interlayer insulating layer 211 such as an NSG layer covering the transistors 10 to 30 is formed. In addition, an interlayer insulating layer 212 such as a TEOS layer covering the interlayer insulating layer 211 is formed. Further, a mask pattern 91 having a plurality of hole patterns 91h is formed on the interlayer insulating layer 212. The mask pattern 91 is, for example, a resist pattern in which a hole pattern 91h is provided in a resin layer such as a resist layer.

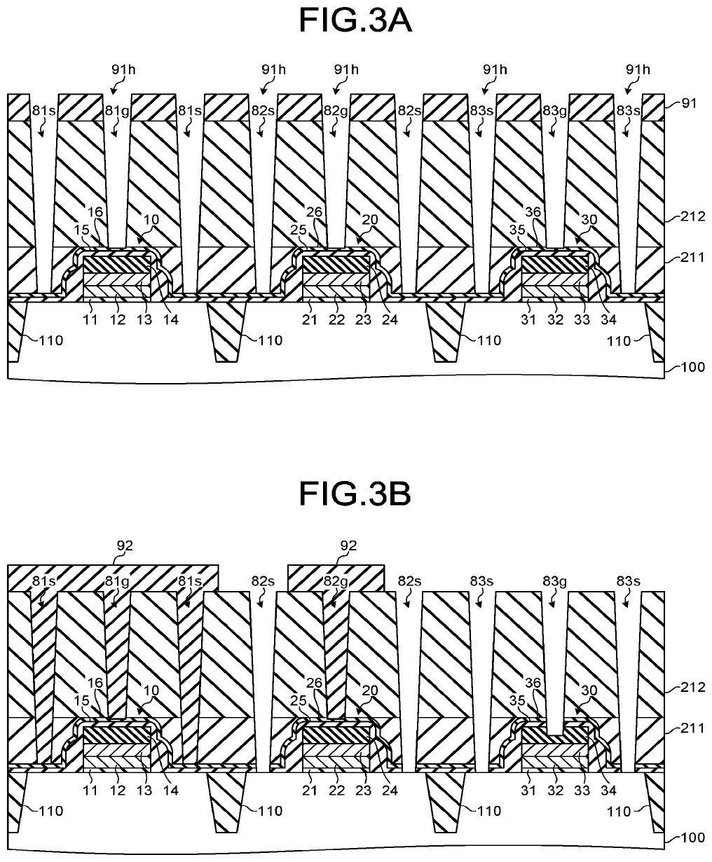

As illustrated in FIG. 3A, the interlayer insulating layers 212 and 211 are etched through the mask pattern 91 to form a plurality of contact holes 81s to 83s and 81g to 83g.

The pair of contact holes 81s reach the liner layer 16 on the substrate 100 on both sides of the transistor 10. The pair of contact holes 82s reach the liner layer 26 on the substrate 100 on both sides of the transistor 20. The pair of contact holes 83s reach the liner layer 36 on the substrate 100 on both sides of the transistor 30.

The contact holes 81g to 83g penetrate the interlayer insulating layers 212 and 211 and reach the liner layers 16 to 36 covering the transistors 10 to 30, respectively. At this time, an etching condition having high selectivity with respect to the liner layers 16 to 36 is used. As a result, the lower ends of the contact holes 81g to 83g shallower than the contact holes 81s to 83s do not penetrate the liner layers 16 to 36 and remain in the upper surface of the liner layers 16 to 36 or the liner layers 16 to 36, respectively.

Thereafter, the mask pattern 91 is removed by asking treatment or the like using oxygen plasma.

As illustrated in FIG. 3B, a mask pattern 92 such as a resist pattern having openings at positions where contact holes 82s, 83s, 83g are formed is formed on the interlayer insulating layer 212. As a result, the other contact holes 81s, 81g, and 82g are covered with the mask pattern 92. The mask material constituting the mask pattern 92 may be filled partially or entirely in the contact holes 81s, 81g, and 82g.

Further, the liner layers 26 and 36 and the spacer layers 25 and 35 are removed from the bottom surfaces of the contact holes 82s, 83s, and 83g not covered with the mask pattern 92. On the bottom surface of the contact hole 83g, a part of the cap layer 34 is further removed by etching, and the lower end of the contact hole 83g reaches a predetermined depth of the cap layer 34.

Thereafter, the mask pattern 92 is removed by asking treatment or the like using oxygen plasma.

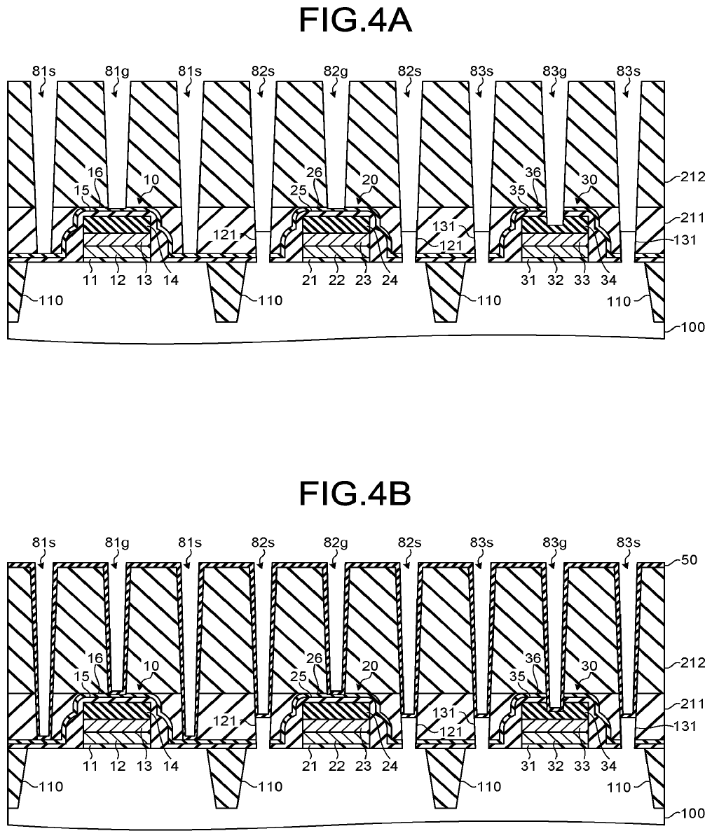

As illustrated in FIG. 4A, epitaxial layers 121 and 131 such as a crystalline silicon layer are formed by epitaxial growth on the substrate 100 exposed on the bottom surfaces of the contact holes 82s and 83s. No epitaxial layer is formed at the lower ends of the contact holes 81s, 81g, and 82g located on the liner layers 16 and 26, respectively, and at the lower end of the contact hole 83g located in the cap layer 34.

As illustrated in FIG. 4B, an insulating layer 50 such as an LTO layer is formed on the interlayer insulating layer 212. The insulating layer 50 is also formed on the sidewall and a bottom surface in each of the contact holes 81s to 83s and 81g to 83g.

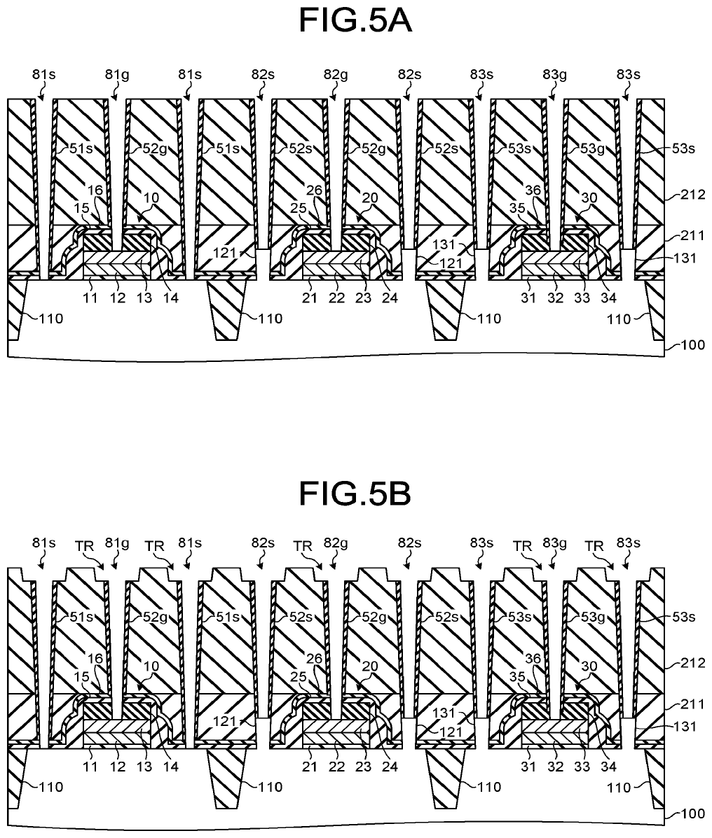

As illustrated in FIG. 5A, the insulating layer 50 on the bottom surfaces of the contact holes 81s to 83s and 81g to 83g is removed. As a result, the upper surface of the epitaxial layers 121 and 131 is exposed from the bottom surfaces of the contact holes 82s and 83s.

On the other hand, in the contact hole 81s, the liner layer 16 and the spacer layer 15 on the bottom surface of the contact hole 81s are also removed, and the upper surface of the substrate 100 is exposed.

In the contact holes 81g and 82g, the liner layers 16 and 26 and the spacer layers 15 and 25 on the bottom surfaces of the contact holes 81g and 82g are removed, and the cap layers 14 and 24 are also removed by etching. As a result, the lower ends of the contact holes 81g and 82g penetrate the cap layers 14 and 24 and reach the metal electrodes 13 and 23.

In the contact hole 83g, the remaining cap layer 34 is removed by etching. As a result, the lower end of the contact hole 83g penetrates the cap layer 34 and reaches the metal electrode 33.

In addition, when the insulating layer 50 on the bottom surfaces of the contact holes 81s to 83s and 81g to 83g is removed, the insulating layer 50 on the upper surface of the interlayer insulating layer 212 is also removed. As a result, the contact holes 81s to 83s and 81g to 83g have the insulating layers 51s to 53s and 51g to 53g on the respective sidewalls.

However, in the contact hole 81s, the reaching depth of the insulating layer 51s remains in the upper surface of the liner layer 16 or the liner layer 16, and the insulating layer 51s is not provided at least below the contact hole 81s penetrating the spacer layer 15.

In addition, in the contact holes 81g and 82g, the reaching depths of the insulating layers 51g and 52g remain in the upper surfaces of the liner layers 16 and 26 or the liner layers 16 and 26, respectively, and the insulating layers 15g and 25g are not provided at least below the contact holes 81g and 82g penetrating the spacer layers 14 and 24 and the cap layers 51 and 52.

In the contact hole 83g, the reaching depth of the insulating layer 53g reaches a predetermined depth in the cap layer 34 beyond the liner layer 36 and the spacer layer 35. The contact hole 83g does not have the insulating layer 53g below the contact hole 83g extending from the predetermined depth of the cap layer 34 to the metal electrode 33.

In the contact holes 82s and 83s, the insulating layers 52s and 53s cover the entire sidewalls of the contact holes 82s and 83s up to the lower portions of the contact holes 82s and 83s reaching the epitaxial layers 121 and 131, respectively.

As illustrated in FIG. 5B, a plurality of trenches TR connected to the upper ends of the contact holes 81s to 83s and 81g to 83g are formed in the interlayer insulating layer 212.

Thereafter, a metal layer such as a tungsten layer or a copper layer is filled in the contact holes 81s to 83s and 81g to 83g and the trenches TR.

As a result, conductive layers 61s to 63s and 61g to 63g are formed in the contact holes 81s to 83s and 81g to 83g, respectively, and a plurality of contacts 71s to 73s and 71g to 73g are obtained. In addition, a plurality of wirings DO connected to these contacts 71s to 73s and 71g to 73g are obtained.

However, the filling of the metal layer into the contact holes 81s to 83s and 81g to 83g and the filling of the metal layer into the trenches TR may be performed separately. In this case, the inside of the contact holes 81s to 83s and 81g to 83g and the inside of the trenches TR may be filled with different metal layers.

In this way, the semiconductor device 1 according to the embodiment is manufactured.

### Comparative Example

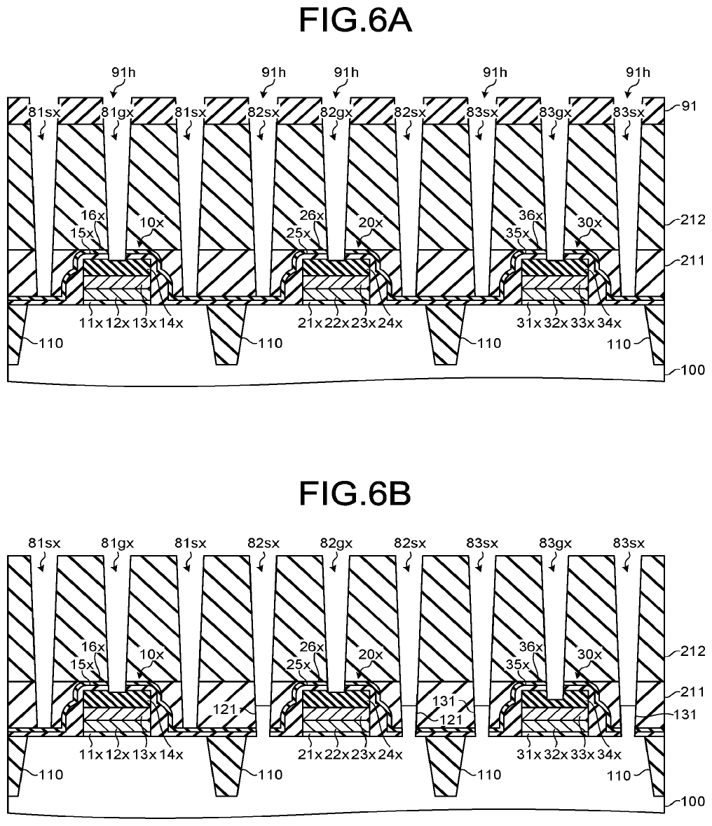

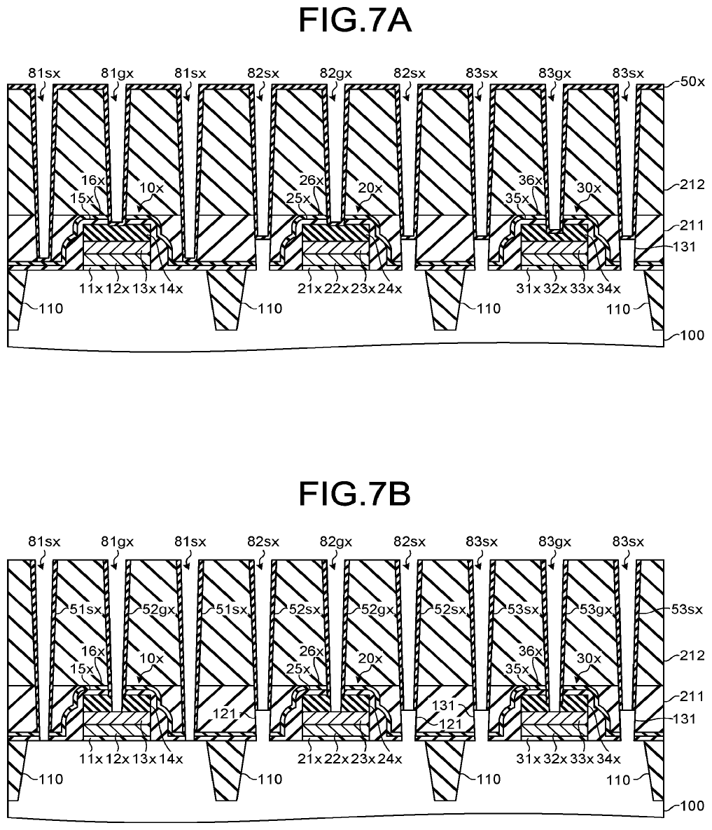

Next, a method for manufacturing a semiconductor device according to a comparative example will be described with reference to FIGS. 6A to 7B. FIGS. 6A to 7B are cross-sectional views sequentially illustrating a part of the procedure of the method for manufacturing the semiconductor device according to the comparative example.

Also in the semiconductor device of the comparative example, the processing of FIGS. 2A to 3A is performed. As a result, as illustrated in FIG. 6A, transistors 12x to 32x of the comparative example including gate insulating layers 11x to 31x, polysilicon electrodes 10x to 30x, metal electrodes 13x to 33x, cap layers 14x to 34x, and spacer layers 15x to 35x and liner layers 16x to 36x covering these layers are formed, and contact holes 81sx to 83sx and 81gx to 83gx of the comparative example are formed above these transistors 10x to 30x.

However, in the semiconductor device of the comparative example, the lower ends of the contact holes 81gx to 83gx penetrate the liner layers 16x to 36x and the spacer layers 15x to 35x, and reach the cap layers 14x to 34x, respectively. Such contact holes 81gx to 83gx are obtained by, for example, performing excessive over-etching on the contact holes 81gx to 83gx having shallower reaching depths than the contact holes 81sx to 83sx.

As illustrated in FIG. 6B, the liner layers 26x and 36x and the spacer layers 25x and 35x on the bottom surfaces of the contact holes 82sx and 83sx are removed, respectively. At that time, similarly to the mask pattern 92 illustrated in FIG. 3B, a mask pattern having openings at formation positions of the contact holes 82sx, 83sx, and 83gx is formed on the interlayer insulating layer 212. As a result, on the bottom surface of the contact hole 83gx, a part of the cap layer 34x is also etched away. Further, the epitaxial layers 121 and 131 are formed on the upper surface of the substrate 100 exposed from the bottom surfaces of the contact holes 82sx and 83sx.

As illustrated in FIG. 7A, the insulating layer 212x is formed on the upper surface of the interlayer insulating layer 50 and the sidewalls and the bottom surface in the contact holes 81sx to 83sx and 81gx to 83gx.

As illustrated in FIG. 7B, the insulating layer 50x on the bottom surface of the contact holes 81sx to 83sx and 81gx to 83gx is removed. At this time, the insulating layer 212x on the interlayer insulating layer 50 is also removed, and the contact holes 81sx to 83sx and 81gx to 83gx have the insulating layers 51sx to 53sx and 51gx to 53gx on the respective sidewalls.

In addition, the liner layer 81x and the spacer layer 16x on the bottom surface of the contact hole 15sx are removed to expose the upper surface of the substrate 100. The lower ends of the contact holes 81gx to 83gx penetrate the cap layers 14x to 34x and reach the metal electrodes 13x to 33x, respectively.

Thereafter, similarly to the semiconductor device 1 of the above-described embodiment, a plurality of trenches connected to the upper ends of the contact holes 81sx to 83sx and 81gx to 83gx are formed, and the inside of the contact holes 81sx to 83sx and 81gx to 83gx and the inside of the trenches are filled with a metal layer.

In this way, the semiconductor device of the comparative example is manufactured.

In the semiconductor device of the comparative example manufactured as described above, characteristics of the transistors 10x and 20x and the like may vary. The present inventors have considered that such variations in characteristics are caused by mixing of hydrogen into the transistors 10x and 20x. Such hydrogen is considered to be derived from, for example, hydrogen contained in a constituent material such as the interlayer insulating layers 211 and 212 covering the transistors 10x and 20x. Hydrogen in the constituent material may remain in the interlayer insulating layers 211 and 212 even after the formation of the interlayer insulating layers 211 and 212.

In general, a dopant serving as a channel stopper is implanted into the sidewalls of an element isolation layer that isolates a transistor. When hydrogen is mixed into the transistor, the dopant injected into the sidewalls of the element isolation layer is inactivated, and for example, a leakage current between adjacent transistors may increase. In addition, the resistance value at the interface between the polysilicon electrode and the metal electrode may increase.

On the other hand, when hydrogen is mixed into the transistor, a dangling bond at an interface between silicon or the like constituting the substrate and the gate electrode is terminated, and for example, in a P-channel MOS transistor or the like, improvement of negative bias temperature instability (NBTI) can be expected.

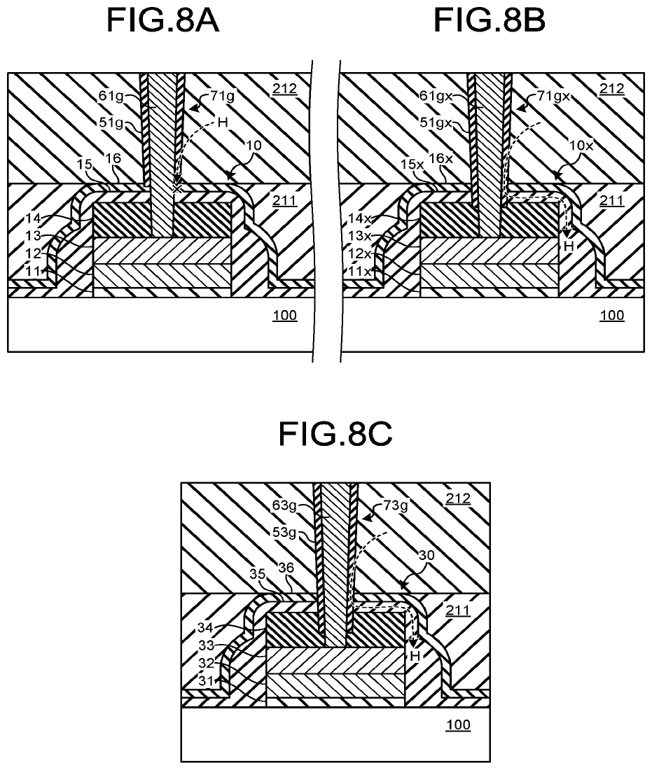

Hereinafter, a difference between the semiconductor device 1 of the embodiment and the semiconductor device of the comparative example will be described with reference to FIGS. 8A to 8C.

FIGS. 8A to 8C are partially enlarged cross-sectional views of the semiconductor device according to the embodiment and the comparative example. More specifically, FIG. 8A is a cross-sectional view of the transistor 10 of the semiconductor device 1 of the embodiment, FIG. 8B is a cross-sectional view of the transistor 10x of the semiconductor device of the comparative example, and FIG. 8C is a cross-sectional view of the transistor 30 of the semiconductor device 1 of the embodiment.

As illustrated in FIG. 8B, in the transistor 10x of the comparative example, the contact 10gx connected to the metal electrode 13x of the transistor 71x has an insulating layer 16gx that penetrates the liner layer 15x and the spacer layer 14x and reaches the cap layer 51x.

The silicon nitride layer or the like used for the liner layer 16x is, for example, a dense layer as compared with a silicon oxide layer or the like, and prevents mixing of hydrogen from the interlayer insulating layers 211 and 212 into the transistor 10x. The present inventors have estimated that hydrogen is mixed into the transistor 10x via the insulating layer 51gx penetrating the liner layer 16x and reaching the inside of the transistor 10x.

As described above, the increase in the leakage current between the transistors 10x caused by deactivation of the dopant on the sidewalls of the element isolation layer by the mixed hydrogen can be a factor of significantly deteriorating the characteristics of the transistors 10x arranged at high density in the drive circuit as the main configuration of the drive circuit, for example.

Also in the transistor 20x of the comparative example, it is considered that hydrogen is mixed into the transistor 20x via the insulating layer 52gx of the contact 72gx that penetrates the liner layer 26x and reaches the inside of the transistor 20x.

As described above, the increase in the resistance value at the interface between the polysilicon electrode and the metal electrode due to the mixed hydrogen may cause, for example, a decrease in the operation speed of the transistor 20x required to operate at a high speed in the drive circuit, and may cause a significant decrease in the characteristics of the transistor 20x.

As illustrated in FIG. 8A, in the transistor 10 of the embodiment, the insulating layer 10g of the contact 71g connected to the metal electrode 13 of the transistor 51 remains in the upper surface of the liner layer 16 or the liner layer 16, and does not penetrate the liner layer 16 and enter the transistor 10.

Therefore, mixing of residual hydrogen or the like in the interlayer insulating layers 211 and 212 into the transistor 10 is prevented by the liner layer 16x which is a dense silicon nitride layer or the like. In addition, since the insulating layer 51g does not penetrate the liner layer 16, mixing of hydrogen into the transistor 10 via the insulating layer 51g is also suppressed.

As a result, for example, in the transistors 10 arranged at a high density in the drive circuit as a main configuration of the drive circuit, an increase in leakage current between the adjacent transistors 10 is suppressed, and the characteristics of the transistors 10 can be improved.

Also in the transistor 20 of the embodiment, the liner layer 26 covering the transistor 20 prevents mixing of hydrogen into the transistor 20, and also prevents mixing of hydrogen into the transistor 20 via the insulating layer 52g.

As a result, for example, a decrease in the operation speed of the transistor 20 required to operate at a high speed is suppressed, and the characteristics of the transistor 20 can be improved.

On the other hand, in a transistor configured as a P-channel MOS transistor and used as an auxiliary configuration of a drive circuit as in the transistor 30 of the above-described embodiment, an increase in threshold voltage due to NBTI can cause more serious deterioration of the transistor than an increase in leakage current between transistors due to mixing of hydrogen into the transistor.

As illustrated in FIG. 8C, in the transistor 30 of the embodiment, the insulating layer 30g of the contact 73g connected to the metal electrode 33 of the transistor 53 penetrates the liner layer 36 and enters the transistor 30.

As a result, in the transistor 30, residual hydrogen and the like in the interlayer insulating layers 211 and 212 are appropriately introduced into the transistor 30 via the insulating layer 53g. Therefore, the NBTI of the transistor 30 can be improved to suppress the fluctuation of the threshold voltage, and the reliability of the transistor 30 can be improved.

(Overview)

According to the semiconductor device 1 of the embodiment, the insulating layer 73g of the contact 53g connected to the metal electrode 33 of the transistor 30 covers the conductive layer 36g of the contact 73g from the upper side to the lower side of the liner layer 63. As a result, it is possible to improve the NBTI of the transistor 30 by introducing hydrogen into the transistor 30 and to improve the reliability of the transistor 30.

According to the semiconductor device 1 of the embodiment, the insulating layer 71g of the contact 51g connected to the metal electrode 13 of the transistor 10 extends from above the liner layer 16 to the liner layer 16 and remains on the liner layer 16 or in the liner layer 16. As a result, it is possible to suppress mixing of hydrogen into the transistor 10, suppress an increase in leakage current between the adjacent transistors 10, and improve the characteristics of the transistor 10.

According to the semiconductor device 1 of the embodiment, the insulating layer 72g of the contact 52g connected to the metal electrode 23 of the transistor 20 extends from above the liner layer 26 to the liner layer 26 and remains on the liner layer 26 or in the liner layer 26. As a result, mixing of hydrogen into the transistor 20 can be suppressed, a decrease in the operation speed of the transistor 20 can be suppressed, and the characteristics of the transistor 20 can be improved.

(First Modification)

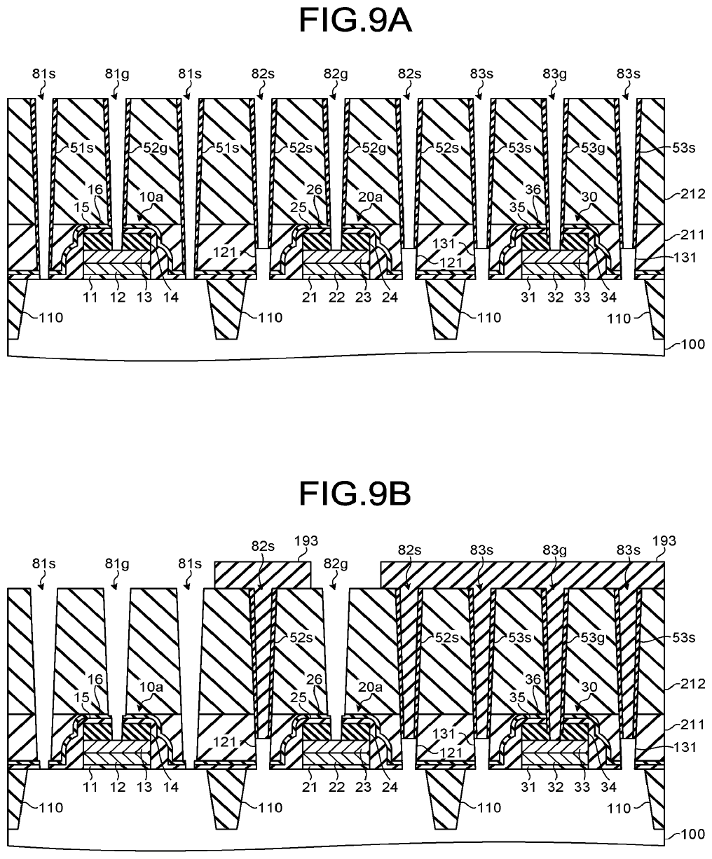

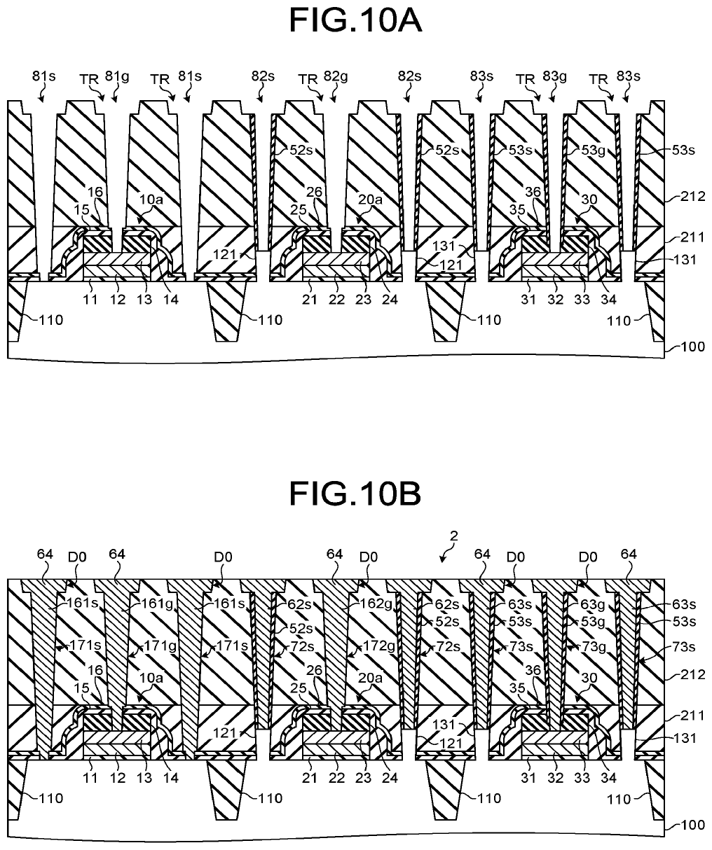

Next, a semiconductor device 2 according to a first modification of the embodiment will be described with reference to FIGS. 9A to 10B. The semiconductor device 2 of the first modification is different from that of the above-described embodiment in that the contact 171g connected to the transistor 10a, which is a high-voltage N-channel MOS transistor or the like, and the transistor 20a, which is a low-voltage P-channel MOS transistor or the like, do not have an insulating layer.

FIGS. 9A to 10B are cross-sectional views sequentially illustrating a part of the procedure of the method for manufacturing the semiconductor device 2 according to the first modification of the embodiment. Note that, in FIGS. 9A to 10B, the same components as those of the semiconductor device 1 of the above-described embodiment are denoted by the same reference numerals, and the description thereof may be omitted.

Also in the semiconductor device 2 of the first modification, the processing of FIGS. 2A to 5A is performed. As a result, as illustrated in FIG. 9A, transistors 10a, 20a, and 30 of the first modification and contact holes 81s to 83s and 81g to 83g connected to these transistors 10a, 20a, and 30 are formed.

Note that, in the processing so far, the transistors 10a and 20a have the same configuration as the transistors 10 and 20 of the above-described embodiments. However, for convenience of description, in order to distinguish from the transistors 10 and 20 of the above-described embodiment, they are referred to as transistors 10a and 20a in the first modification.

As illustrated in FIG. 9B, a mask pattern 193 such as a resist pattern having openings in the contact holes 81s, 81g, and 82g is formed on the interlayer insulating layer 212. As a result, the other contact holes 82s, 83s, and 83g are covered with the mask pattern 193. The mask material constituting the mask pattern 193 may be filled partially or entirely in the contact holes 82s, 83s, and 83g.

Further, the insulating layers 51s, 51g, and 52g on the sidewalls of the contact holes 81s, 81g, and 82g, which are not covered with the mask pattern 92, are removed by wet etching or the like. At this time, steps may be generated between portions of the contact holes 81s, 81g, and 82g originally covered with the insulating layers 51s, 51g, and 52g and lower ends of the contact holes 81s, 81g, and 82g below the portions.

That is, in the contact holes 81s, 81g, and 82g, the insulating layers 51s, 51g, and 52g may be removed to expand the apparent diameters of the portions, and for example, the contact holes 81s, 81g, and 82g may have steps on the sidewalls at the height positions of the liner layers 16 and 26, respectively. In addition, the apparent diameters of the contact holes 81s, 81g, and 82g may be narrowed below these steps.

Thereafter, the mask pattern 193 is removed by asking treatment or the like using oxygen plasma.

As illustrated in FIG. 10A, a plurality of trenches TR connected to the upper ends of the contact holes 81s to 83s and 81g to 83g are formed in the interlayer insulating layer 212.

As illustrated in FIG. 10B, a metal layer such as a tungsten layer or a copper layer is collectively or separately filled in the contact holes 81s to 83s and 81g to 83g and the trenches TR.

As a result, conductive layers 161s, 62s, 63s, 161g, 162g, and 63g are formed in the contact holes 81s to 83s and 81g to 83g, respectively, and a plurality of contacts 171s, 72s, 73s, 171g, 172g, and 73g are formed. In addition, a plurality of wirings DO connected to the contacts 171s, 72s, 73s, 171g, 172g, and 73g are formed.

As described above, when steps are formed in the contact holes 81s, 81g, and 82g, the conductive layers 81s, 81g, and 82g filled in the contact holes 161s, 161g, and 162g also have steps.

That is, in this case, the respective conductive layers 161s, 161g, and 162g of the contacts 171s, 171g, and 172g may have steps, for example, at the height positions of the liner layers 16 and 26, respectively. In addition, the diameters of the conductive layers 161s, 161g, and 162g may be narrowed below these steps.

In this way, the semiconductor device 2 of the first modification is manufactured.

According to the semiconductor device 2 of the first modification, the conductive layers 161a and 162a of the contacts 171g and 172g connected to the metal electrodes 13 and 23 of the transistors 10g and 20g are in direct contact with the liner layers 16 and 26 on the side surface, respectively, over the entire thickness direction of the liner layers 16 and 26. As a result, as described below, mixing of hydrogen can be further suppressed, and the characteristics of the transistors 10a and 20a can be further improved.

For example, in the process of forming the contact holes 81g and 82g illustrated in FIG. 3A described above, there is a possibility that the etching selectivity with respect to the liner layers 16 and 26 is not sufficiently obtained, and the lower ends of the contact holes 81g and 82g penetrate the liner layers 16 and 26. In this case, the insulating layers 51g and 52g formed on the sidewalls of the contact holes 81g and 82g thereafter go beyond the liner layers 16 and 26 and enter the transistors 10a and 20a.

However, in the contacts 171g and 172g of the first modification, the insulating layers 51g and 52g covering the sidewalls of the conductive layers 161g and 162g are removed. Therefore, even when the lower ends of the contact holes 81g and 82g penetrate the liner layers 16 and 26 and the insulating layers 51g and 52g enter the transistors 10a and 20a, it is possible to suppress mixing of hydrogen into the transistors 10a and 20a via the insulating layers 51g and 52g.

According to the semiconductor device 2 of the first modification, other effects similar to those of the semiconductor device 1 of the above-described embodiment are obtained.

(Second Modification)

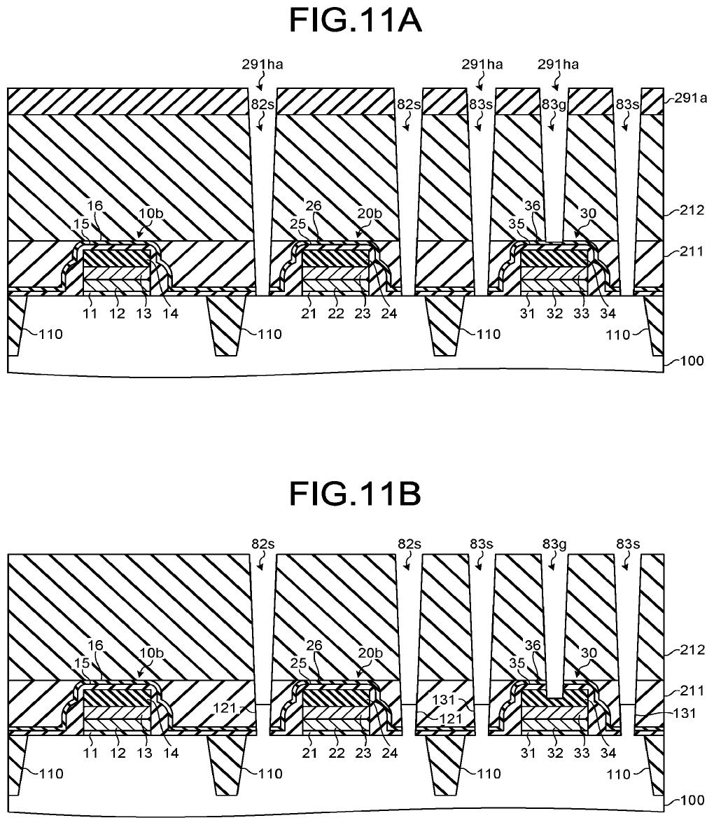

As described above, the contact having no insulating layer on the sidewall of the conductive layer can also be obtained by forming the contact connected to the individual transistor in a separate process. Hereinafter, a method for manufacturing a semiconductor device different from that of the first modification will be described with reference to FIGS. 11A to 14B.

FIGS. 11A to 14B are cross-sectional views sequentially illustrating a part of the procedure of the method for manufacturing a semiconductor device 3 according to the second modification of the embodiment. Note that, in FIGS. 11A to 14B, the same components as those of the semiconductor device 1 of the above-described embodiment are denoted by the same reference numerals, and the description thereof may be omitted.

Also in the semiconductor device 3 of the second modification, the above-described processing of FIGS. 2A and 2B is performed. As a result, as illustrated in FIG. 11A, the transistors 10b, 20b, and 30 of the second modification are formed. In addition, similarly to FIG. 2C described above, the interlayer insulating layers 211 and 212 covering the transistors 10b, 20b, and 30 is sequentially formed.

Note that, in the processing so far, the transistors 10b and 20b have the same configuration as the transistors 10 and 20 of the above-described embodiments. However, for convenience of description, in order to distinguish from the transistors 10 and 20 of the above-described embodiment, they are referred to as transistors 10b and 20b in the second modification.

Further, a mask pattern 291a such as a resist pattern having a plurality of hole patterns 291ha is formed on the interlayer insulating layer 212.

The interlayer insulating layers 212 and 211, the liner layers 26 and 36, and the spacer layers 25 and 35 are etched via the mask pattern 291a to form the plurality of contact holes 82s, 83s, and 83g.

As a result, the contact holes 82s and 83s penetrate the interlayer insulating layers 212 and 211, the liner layers 26 and 36, and the spacer layers 25 and 35, and reach the substrate 100 on both sides of the transistors 20b and 30. The contact hole 83g penetrates the interlayer insulating layers 212 and 211, the liner layer 36, and the spacer layer 35, and reaches a predetermined depth of the cap layer 34.

Thereafter, the mask pattern 291a is removed by asking treatment or the like using oxygen plasma.

As illustrated in FIG. 11B, an epitaxial layers 121 and 131 such as a crystalline silicon layer is formed by epitaxial growth on the substrate 100 exposed on the bottom surfaces of the contact holes 82s and 83s.

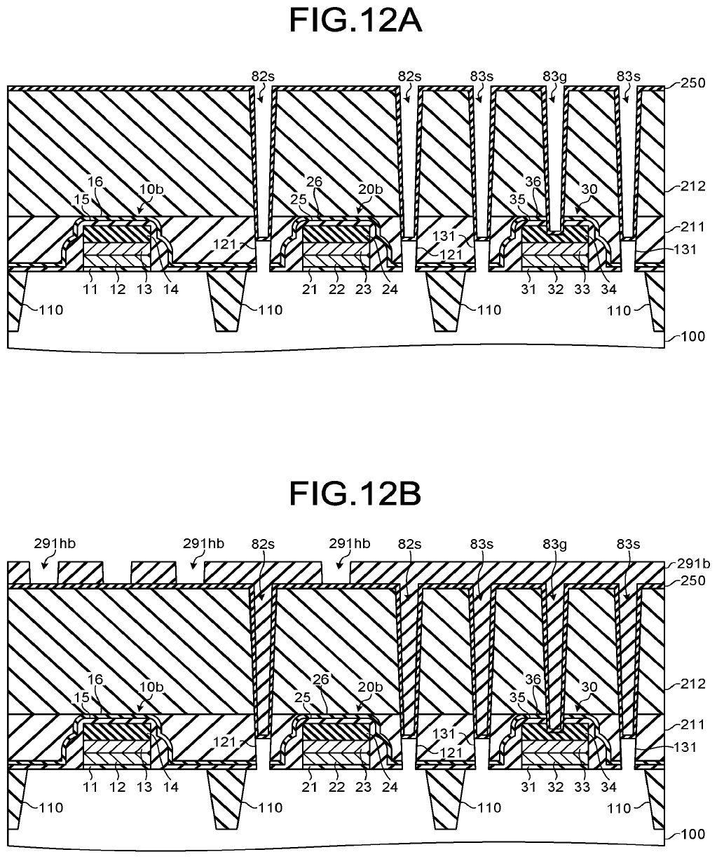

As illustrated in FIG. 12, an insulating layer 250 such as an LTO layer is formed on the upper surface of the interlayer insulating layer 212. The insulating layer 250 is also formed on the sidewalls and a bottom surface in each of the contact holes 82s, 83s, and 83g.

As illustrated in FIG. 12B, a mask pattern 291b such as a resist pattern having a plurality of hole patterns 291hb and covering the contact holes 82s, 83s, and 83g is formed on the interlayer insulating layer 212. At this time, a mask material constituting the mask pattern 291b may be filled partially or entirely in the contact holes 82s, 83s, and 83g.

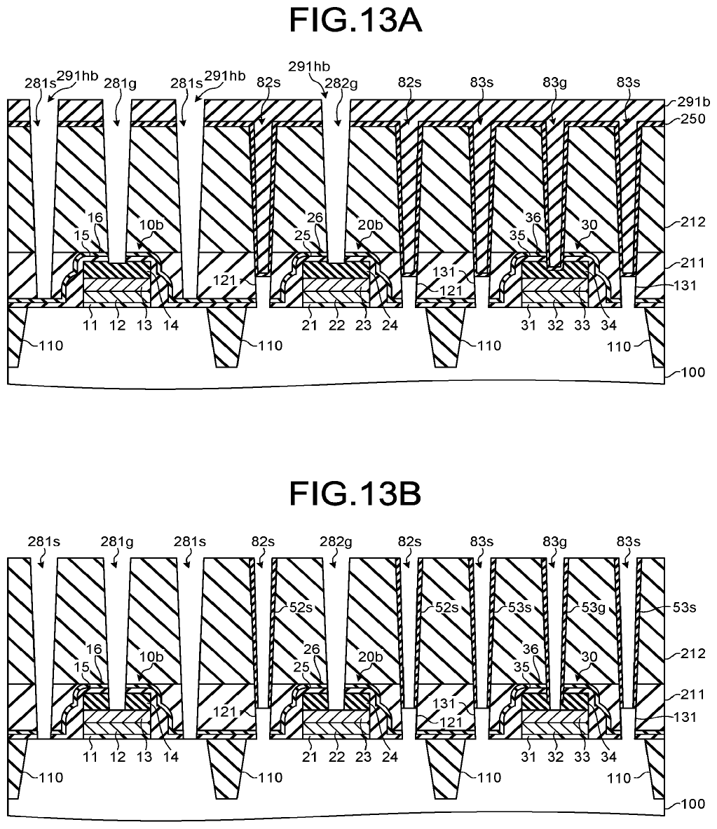

As illustrated in FIG. 13A, the interlayer insulating layers 212 and 211 is etched through the mask pattern 291b to form the plurality of contact holes 281s, 281g, and 282g. At this time, for example, excessive over-etching is performed on the contact holes 281g and 281gx having shallower reaching depths than the contact hole 282s.

As a result, the lower end of the contact hole 281s reaches the liner layer 16 on the substrate 100 on both sides of the transistor 10b. The lower ends of the contact holes 281g and 282g penetrate the liner layers 16 and 26 and the spacer layers 15 and 25, and reach the cap layers 14 and 24, respectively.

Thereafter, the mask pattern 291b is removed by asking treatment or the like using oxygen plasma.

As illustrated in FIG. 13B, the insulating layer 250 on the bottom surfaces of the contact holes 82s, 83s, and 83g is removed. At this time, the insulating layer 250 on the interlayer insulating layer 212 is also removed. As a result, the contact holes 82s, 83s, and 83g have the insulating layers 52s, 53s, and 53g on the sidewalls, respectively.

In addition, the liner layer 16 and the spacer layer 15 on the bottom surface of the contact hole 281s are removed, and the lower end of the contact hole 281s reaches the substrate 100. Further, the lower ends of the contact holes 281g, 282g, and 83g penetrate the cap layers 14 to 34 and reach the metal electrodes 13 to 33, respectively.

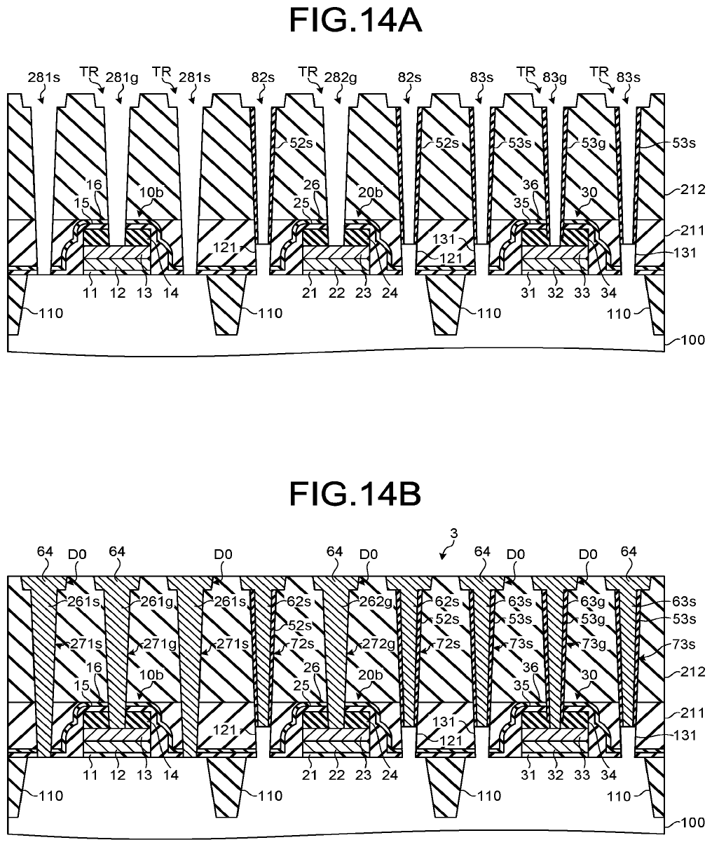

As illustrated in FIG. 14A, a plurality of trenches TR connected to the upper ends of the contact holes 281s, 82s, 83s, 281g, 282g, and 83g are formed in the interlayer insulating layer 212.

As illustrated in FIG. 14B, a metal layer such as a tungsten layer and a copper layer is collectively or separately filled in the contact holes 281s, 82s, 83s, 281g, 282g, and 83g and the trenches TR.

As a result, conductive layers 261s, 62s, 63s, 261g, 262g, and 63g are formed in the contact holes 281s, 82s, 83s, 281g, 282g, and 83g, respectively, and a plurality of contacts 271s, 72s, 73s, 271g, 272g, and 73g are obtained. In addition, a plurality of wirings DO connected to the contacts 271s, 72s, 73s, 271g, 272g, and 73g are obtained.

In the above method, since the insulating layer 250 is not formed in the contact holes 281s, 281g, and 282g from the beginning, the conductive layers 261s, 261g, and 262g filling the contact holes 281s, 281g, and 282g and the contact holes 281s, 281g, and 282g, respectively, do not have steps as in the first modification described above.

According to the semiconductor device 3 of the second modification, the conductive layers 261g and 262g of the contacts 271g and 272g connected to the metal electrodes 13 and 23 of the transistors 10b and 20b are in direct contact with the liner layers 16 and 26 on the side surface, respectively, over the entire thickness direction of the liner layers 16 and 26. In this way, since the contacts 271g and 272g do not have an insulating layer from the beginning, it is possible to further suppress mixing of hydrogen and to further improve the characteristics of the transistors 10b and 20b.

According to the semiconductor device 3 of the second modification, the contacts 271s, 72s, 73s, 271g, 272g, and 73g connected to the transistors 10b, 20b, and 30 are separately formed. As a result, although the number of manufacturing processes of the semiconductor device 3 increases, the individual contacts 271s, 72s, 73s, 271g, 272g, and 73g can be formed more precisely.

According to the semiconductor device 3 of the second modification, other effects similar to those of the semiconductor device 1 of the above-described embodiment are obtained.

[Application Example of Semiconductor Device]

The configuration of the above-described embodiment and the first and second modifications can be applied to, for example, a transistor or the like provided around a memory cell of a semiconductor memory device and constituting a drive circuit for driving the memory cell. Hereinafter, a configuration example of a semiconductor memory device including a transistor to which the configuration of any one of the above-described embodiment and the first and second modifications is applied will be described with reference to the drawings.

(Schematic Configuration of Semiconductor Memory Device)

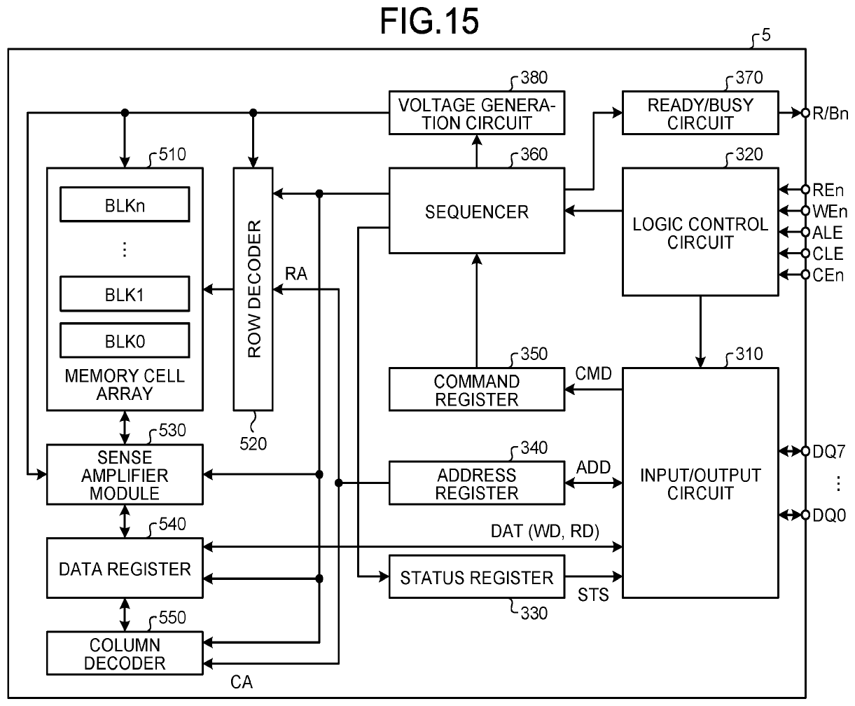

FIG. 15 is a block diagram of a semiconductor memory device 5 according to another embodiment. As illustrated in FIG. 15, the semiconductor memory device 5 includes an input/output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input/output circuit 310 controls input/output of a signal DQ to/from an external device such as a memory controller (not illustrated) that controls the semiconductor memory device 5. The input/output circuit 310 includes an input circuit and an output circuit (not illustrated).

The input circuit transmits the data DAT such as the write data WD received from the external device to the data register 540, transmits the address ADD to the address register 340, and transmits the command CMD to the command register 350.

The output circuit transmits the status information STS received from the status register 330, the data DAT such as the read data RD received from the data register 540, and the address ADD received from the address register 340 to the external device.

The logic control circuit 320 receives, for example, a chip enable signal CEn, a command latch enable signal CLE, an address latch enable signal ALE, a write enable signal WEn, and a read enable signal REn from an external device. In addition, the logic control circuit 320 controls the input/output circuit 310 and the sequencer 360 according to the received signal.

The status register 330 temporarily holds status information STS in, for example, a write operation, a read operation, and an erase operation of data, and notifies the external device whether or not the operation is normally ended.

The address register 340 temporarily holds the address ADD received from the external device via the input/output circuit 310. In addition, the address register 340 transfers the row address RA to the row decoder 520 and transfers the column address CA to the column decoder 550.

The command register 350 temporarily stores the command CMD received from the external device via the input/output circuit 310 and transfers the command CMD to the sequencer 360.

The sequencer 360 controls the entire operation of the semiconductor memory device 5. More specifically, the sequencer 360 controls, for example, the status register 330, the ready/busy circuit 370, the voltage generation circuit 380, the row decoder 520, the sense amplifier module 530, the data register 540, the column decoder 550, and the like according to the command CMD held by the command register 350, and executes a write operation, a read operation, an erase operation, and the like.

The ready/busy circuit 370 transmits a ready/busy signal R/Bn to an external device according to the operation status of the sequencer 360.

The voltage generation circuit 380 generates a voltage necessary for the write operation, the read operation, and the erase operation according to the control of the sequencer 360, and supplies the generated voltage to, for example, the memory cell array 510, the row decoder 520, the sense amplifier module 530, and the like. The row decoder 520 and the sense amplifier module 530 apply the voltage supplied from the voltage generation circuit 380 to the memory cells in the memory cell array 510.

The memory cell array 510 includes a plurality of blocks BLK (BLK0 to BLKn). n is an integer of 2 or more. The block BLK is a set of a plurality of memory cells associated with bit lines and word lines, and is, for example, a data erasing unit. The memory cell is configured as, for example, a transistor, and holds nonvolatile data.

By including such a memory cell, the semiconductor memory device 5 is configured as, for example, a NAND nonvolatile memory. However, the semiconductor memory device 5 may be configured as another non-volatile memory such as a NOR type.

The row decoder 520 decodes the row address RA. In addition, the row decoder 520 selects any block BLK on the basis of the decoding result. The row decoder 520 applies a necessary voltage to the block BLK.

The sense amplifier module 530 senses data read from the memory cell array 510 during the read operation. In addition, the sense amplifier module 530 transmits the read data RD to the data register 540. During the write operation, the sense amplifier module 530 transmits write data WD to the memory cell array 510.

The data register 540 includes a plurality of latch circuits. The latch circuit holds write data WD and read data RRD. For example, in the write operation, the data register 540 temporarily holds the write data WD received from the input/output circuit 310 and transmits the write data WD to the sense amplifier module 530. In addition, for example, in the read operation, the data register 540 temporarily holds the read data RD received from the sense amplifier module 530 and transmits the read data RD to the input/output circuit 310.

The column decoder 550 decodes the column address CA at the time of, for example, the write operation, the read operation, and the erase operation, and selects the latch circuit in the data register 540 according to the decoding result.

Each of the above-described configurations of the semiconductor memory device 5 excluding the memory cell array 510 is also referred to as a peripheral circuit. The peripheral circuit is a circuit group arranged around the memory cell array 510, and includes an input/output circuit 310, a logic control circuit 320, a status register 330, an address register 340, a command register 350, a sequencer 360, a ready/busy circuit 370, a voltage generation circuit 380, a row decoder 520, a sense amplifier module 530, a data register 540, and a column decoder 550.

As described above, the semiconductor memory device 5 includes the memory cell array 510 including the plurality of memory cells and the peripheral circuit that operates the plurality of memory cells.

(Circuit Configuration of Memory Cell Array and Row Decoder)

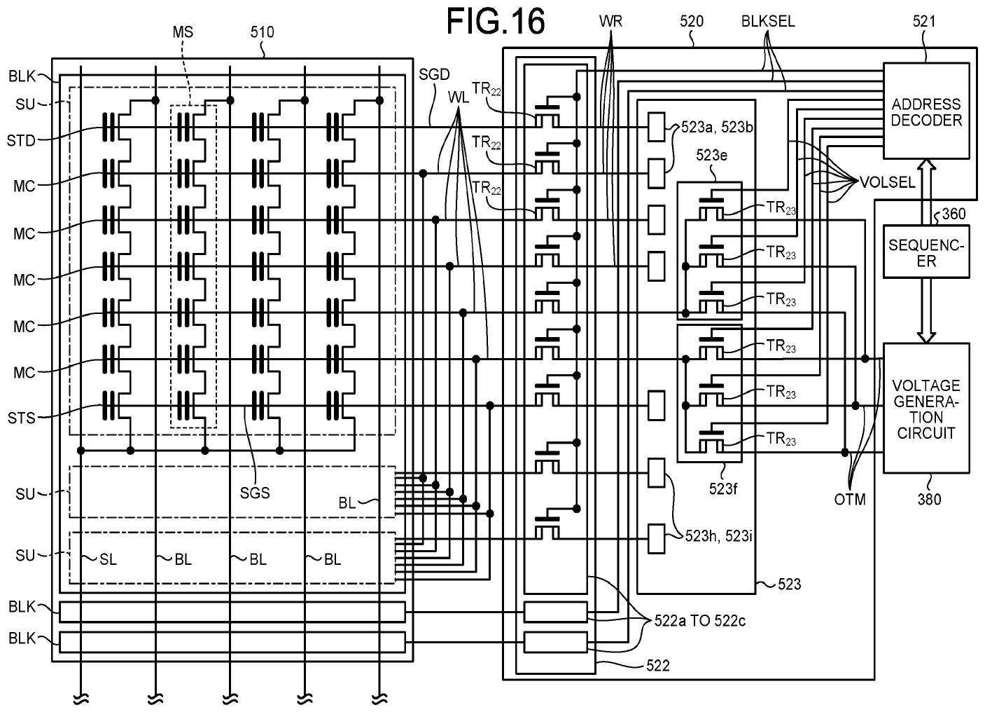

FIG. 16 is an equivalent circuit diagram illustrating an example of a configuration of the memory cell array 510 and the row decoder 520 included in the semiconductor memory device 5 according to another embodiment. First, an example of a circuit configuration of the memory cell array 510 included in the semiconductor memory device 5 will be described below.

The memory cell array 510 includes the plurality of blocks BLK as described above. Each of the plurality of blocks BLK includes a plurality of string units SU. Each of the plurality of string units SU includes a plurality of memory strings MS. One end of each of the plurality of memory strings MS is connected to a peripheral circuit such as the row decoder 520 and the sense amplifier module 530 via the bit line BL. The other ends of the plurality of memory strings MS are each connected to a peripheral circuit via a common source line SL.

The memory string MS includes a drain selection transistor STD connected in series between the bit line BL and the source line SL, a plurality of memory cells MC, and a source selection transistor STS. Hereinafter, the drain selection transistor STD and the source selection transistor STS may be simply referred to as selection transistors (STD, STS).

The memory cell MC is, for example, a field effect transistor (FET) including a charge storage layer in a gate insulating layer. The threshold voltage of the memory cell MC changes according to the charge amount in the charge storage layer. By providing one or a plurality of threshold voltages, the memory cell MC may be capable of storing data of one bit or a plurality of bits. The word line WL is connected to the gate electrodes of the plurality of memory cells MC corresponding to one memory string MS. Each of these word lines WL is commonly connected to all the memory strings MS in one block BLK.

The selection transistor (STD, STS) is, for example, a field effect transistor. A selection gate line (SGD, SGS) is connected to each gate electrode of the selection transistor (STD, STS). The drain select line SGD connected to the drain select transistor STD is provided corresponding to the string unit SU, and is commonly connected to all the memory strings MS in one string unit SU. The source selection line SGS connected to the source selection transistor STS is commonly connected to all the memory strings MS in one block BLK.

Next, a circuit configuration of the row decoder 520 included in the semiconductor memory device 5 will be described.

The row decoder 520 includes an address decoder 521, a block selection circuit 522, and a voltage selection circuit 523. The row decoder 520 includes, for example, transistors TR₂₂ and TR₂₃ to which the configuration of any one of the above-described embodiment and the first and second modifications is applied in these circuits.

The address decoder 521 includes a plurality of block selection lines BLKSEL and a plurality of voltage selection lines VOLSEL.

The address decoder 521 refers to the address data of the address register 340 (see FIG. 15) included in the above-described peripheral circuit, for example, in accordance with a control signal from the sequencer 360.

Furthermore, the address decoder 521 decodes the referred address data, turns on the transistor TR₂₂ and the transistor TR₂₃ corresponding to the address data, and turns off the other transistors TR₂₂ and TR₂₃. Note that the transistor TR₂₂ and the transistor TR₂₃ are transistors included in a block selection circuit 522 and a voltage selection circuit 523 described later, respectively.

In addition, the address decoder 521 sets the voltages of the block selection line BLKSEL and the voltage selection line VOLSEL corresponding to the address data to, for example, an “H” state, and sets the other voltages to an “L” state.

In the example of FIG. 16, in the address decoder 521, one block selection line BLKSEL is provided for each block BLK in the memory cell array 510. However, this configuration can be changed as appropriate. For example, one block selection line BLKSEL may be provided for each of two or more blocks BLK.

The block selection circuit 522 includes a plurality of block selection units 522a to 522c corresponding to the blocks BLK of the memory cell array 510, respectively. Each of the plurality of block selection units 522a to 522c includes a plurality of transistors TR₂₂ corresponding to the word line WL and the selection gate line (SGD, SGS).

The transistor TR₂₂ is, for example, a high-voltage N-channel MOS transistor, and functions as a block drive transistor. The drain electrodes of the transistors TR₂₂ are electrically connected to the corresponding word lines WL or select gate lines (SGD, SGS), respectively. A source electrode of the transistor TR₂₂ is electrically connected to the voltage output terminal OTM via the wiring WR and the voltage selection circuit 523. The gate electrodes of the transistors TR₂₂ are commonly connected to the corresponding block selection line BLKSEL.

Furthermore, the block selection circuit 522 further includes a plurality of transistors (not illustrated). The plurality of transistors are high-voltage CMOS transistors connected between a select gate line (SGD, SGS) and a ground voltage supply terminal. The plurality of transistors cause the select gate line (SGD, SGS) included in the unselected block BLK in the memory cell array 510 to conduct with the ground voltage supply terminal. Note that the plurality of word lines WL included in the unselected block BLK go into a floating state.

The voltage selection circuit 523 includes a plurality of voltage selection units 523a to 523i corresponding to the word line WL and the selection gate line (SGD, SGS). Each of the plurality of voltage selection units 523a to 523i includes a plurality of transistors TR₂₃.

The transistor TR₂₃ is a high-voltage N-channel MOS transistor and functions as a voltage selection transistor. The drain terminal of the transistor TR₂₃ is electrically connected to the corresponding word line WL or selection gate line (SGD, SGS) via the wiring WR and the block selection circuit 522. Each of the source terminals is electrically connected to the corresponding voltage output terminal OTM. Each of the gate electrodes is connected to the corresponding voltage selection line VOLSEL.

As described above, the row decoder 520 belonging to the peripheral circuit includes the plurality of transistors TR₂₂, TR₂₃, and the like. These transistors TR₂₂ and TR₂₃ are transistors that are arranged in the row decoder 520 at a high density and become a main configuration of the row decoder 520, and correspond to, for example, the transistors 10, 10a, and 10b of any one of the above-described embodiment and the first and second modifications.

However, the circuit configuration of the row decoder 520 illustrated in FIG. 16 is an example, and the number and types of the transistors TR₂₂ and TR₂₃, and the like included in the row decoder 520 can be variously different.

In addition to the above, the row decoder 520 includes a high-voltage P-channel MOS transistor, a low-voltage P-channel MOS transistor, and the like that are auxiliary configurations of the row decoder 520. These correspond to, for example, the transistor 30 of any one of the above-described embodiment and the first and second modifications, or the transistors 20, 20a, and 20b.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
first and second gate electrodes;
first and second spacer layers respectively covering the first and second gate electrodes;
first and second liner layers respectively covering the first and second gate electrodes with the first and second spacer layers interposed therebetween;
a first contact extending from above the first liner layer to below the first spacer layer and including a first conductive layer connected to the first gate electrode; and
a second contact extending from above the second liner layer to below the second spacer layer and including a second conductive layer connected to the second gate electrode, wherein
the first conductive layer is in contact with the first spacer layer on a side surface via a first insulating layer covering a sidewall of the first conductive layer, and
the second conductive layer is in direct contact with the second spacer layer on a side surface.

2. The semiconductor device according to claim 1, wherein
the second contact includes a second insulating layer covering the second conductive layer above the second liner layer.

3. The semiconductor device according to claim 2, wherein
the first insulating layer covers the first conductive layer from an upper side to a lower side of the first liner layer, and
the second insulating layer extends from above the second liner layer to the second liner layer and remains on or in the second liner layer.

4. The semiconductor device according to claim 2, wherein
the first and second insulating layers are oxide layers, and
the first and second liner layers are nitride layers.

5. The semiconductor device according to claim 1, further comprising
first and second cap layers on the first and second gate electrodes, respectively, wherein
the first and second conductive layers penetrate the first and second cap layers and are connected to the first and second gate electrodes, respectively.

6. The semiconductor device according to claim 5, wherein
the first insulating layer reaches a predetermined depth of the first cap layer.

7. The semiconductor device according to claim 5, wherein
the second conductive layer is in direct contact with the second cap layer on the side surface.

8. The semiconductor device according to claim 1, wherein
the second conductive layer is in direct contact with the second liner layer on the side surface over an entire thickness direction of the second liner layer.

9. The semiconductor device according to claim 8, wherein
the second conductive layer has a step at a height position of the second liner layer, and
a diameter of the second conductive layer is narrowed at a lower position of the step.

10. The semiconductor device according to claim 1, wherein
the first gate electrode is a gate electrode of a high-voltage P-channel transistor, and
the second gate electrode is a gate electrode of a high-voltage N-channel transistor or a low-voltage P-channel transistor.

11. A semiconductor device comprising:
first and second gate electrodes;
first and second liner layers respectively covering the first and second gate electrodes;
a first contact connected to the first gate electrode; and
a second contact connected to the second gate electrode, wherein
the first contact includes:
a first conductive layer extending downward from above the first liner layer and reaching the first gate electrode; and
a first insulating layer covering a sidewall of the first conductive layer and extending downward from above the first liner layer, and
the second contact includes:
a second conductive layer extending downward from above the second liner layer and reaching the second gate electrode; and
a second insulating layer covering a sidewall of the second conductive layer, the second insulating layer extending from above the second liner layer to the second liner layer and remaining on or in the second liner layer.

12. The semiconductor device according to claim 11, wherein
the first and second insulating layers are oxide layers, and
the first and second liner layers are nitride layers.

13. The semiconductor device according to claim 11, further comprising
first and second cap layers on the first and second gate electrodes, respectively, wherein
the first and second conductive layers penetrate the first and second cap layers and are connected to the first and second gate electrodes, respectively.

14. The semiconductor device according to claim 13, wherein
the first insulating layer reaches a predetermined depth of the first cap layer.

15. The semiconductor device according to claim 13, wherein
the second conductive layer is in direct contact with the second cap layer on the side surface.

16. The semiconductor device according to claim 11, wherein
the first gate electrode is a gate electrode of a high-voltage P-channel transistor, and
the second gate electrode is a gate electrode of a high-voltage N-channel transistor or a low-voltage P-channel transistor.

17. A semiconductor device comprising:
a gate electrode;
a liner layer covering the gate electrode; and
a contact connected to the gate electrode, wherein
the contact includes:
a conductive layer extending downward from above the liner layer and reaching the gate electrode; and
an insulating layer covering a sidewall of the conductive layer, the insulating layer extending from above the liner layer to the liner layer and remaining on or in the liner layer.

18. The semiconductor device according to claim 17, wherein
the insulating layer is an oxide layer, and
the liner layer is a nitride layer.

19. The semiconductor device according to claim 17, further comprising
a cap layer on the gate electrode, wherein
the conductive layer penetrates the cap layer while being in direct contact with the cap layer on a side surface, and is connected to the gate electrode.

20. The semiconductor device according to claim 17, wherein
the gate electrode is a gate electrode of a high-voltage N-channel transistor or a low-voltage P-channel transistor.
